(19) United States
(12) Patent Application Publication
(10) Pub. No.: US 2011/0068181 A1
(43) Pub. Date: Mar. 24, 2011

(54) Multi-modal Security Deterrents And Methods For Generating The Same

(76) Inventors: Steven J. Simske, Fort Collins, CO (US); Jason S. Aronoff, Fort Collins, CO (US)

(21) Appl. No.: 12/992,663

(22) PCT Filed: May 22, 2008
(86) PCT No.: PCT/US08/64486

§ 371 Date: Nov. 15, 2010

(51) Int. Cl. G06K 19/067; H05K 3/10

(52) U.S. Cl. 235/492; 29/846

(57) ABSTRACT

Various multi-modal security deterrents (10) and methods of generating the same are disclosed herein. One embodiment of the deterrent (10) includes first and second sets (12, 16) of 180° phase-insensitive glyphs (14). One or more of the glyphs (14, Gi8o) in the second set (16) are rotated 180° from corresponding glyphs (14, G0) in the first set (12) such that the sets (12, 16) of glyphs (14) have an identical signature pollable by a suitable transmitter/receiver operating in the GHz-THz range and such that the sets (12, 16) of glyphs (14) have a different visual appearance. Data is encoded in one or more of the glyphs (140 of the first set (12) and one or more of the glyphs (14) of the second set (16) such that each set encodes a different message.

### BACKGROUND

The present disclosure relates generally to multi-modal security deterrents and methods for generating the same.

Product labeling and security packaging are important components of product tracking and authenticating, as well as of anti-counterfeiting initiatives. Product labeling and security packaging involve providing each package with a unique ID, in the form of, for example, a deterrent or mark. Such deterrents/marks enable the product to be identified and tracked, and the product inventory to be maintained. Furthermore, measures are often taken to enhance the probability that the product cannot be counterfeited, for example, by making the packaging or labels difficult and/or time consuming to replicate and/or by using variable data printing (VDP).

### BRIEF DESCRIPTION OF THE DRAWINGS

Features and advantages of embodiments of the present disclosure will become apparent by reference to the following detailed description and drawings, in which like reference numerals correspond to the same or similar, though perhaps not identical, components. For the sake of brevity, reference numerals having a previously described function may or may not be described in connection with subsequent drawings in which they appear.

FIG. 1 is a flow diagram depicting an embodiment of the method of generating an embodiment of a multi-modal security deterrent;

FIG. 2 depicts an embodiment of the multi-modal security deterrent generated via the method of FIG. 1;

FIG. 3 is a flow diagram depicting another embodiment of the method of generating another embodiment of a multi-modal security deterrent;

FIGS. 4A and 4B depict an embodiment of the multi-modal security deterrent generated via the method of FIG. 3, where FIG. 4A illustrates the deterrent as it is visible to the human eye, and FIG. 4B illustrates the portion of the deterrent that is visible using reading technology; and

FIGS. 5A and 5B depict an embodiment of the multi-modal security deterrent generated via the method of FIG. 3, where FIG. 5A illustrates the deterrent as it is visible to the human eye, and FIG. 5B illustrates the portion of the deterrent that is visible using reading technology.

### DETAILED DESCRIPTION

Embodiments of the method disclosed herein result in the generation of multi-modal security deterrents suitable for use in security printing. The multi-modal security deterrents disclosed herein may advantageously be authenticated using two or more different authentication techniques (e.g., machine vision, spectral authentication, etc.), and different encoding schemes may be used for each authentication technique. The deterrent may have a valid set of information for each authentication technique; thus, when the deterrent is read, each technology must decode correctly relative to itself and be identified in a backend database (e.g., a remotely/securely accessible database not necessarily located at or near the site of authentication, and accessed via https, ipsec, etc.) as being associated with the other encoding. As such, a would-be counterfeiter must correctly decode all of the encoding schemes, and then determine the accurate relationship between the encoding schemes. Without being bound to any theory, it is believed that these aspects, taken alone or in any combination, render reverse engineering of the deterrent substantially more difficult.

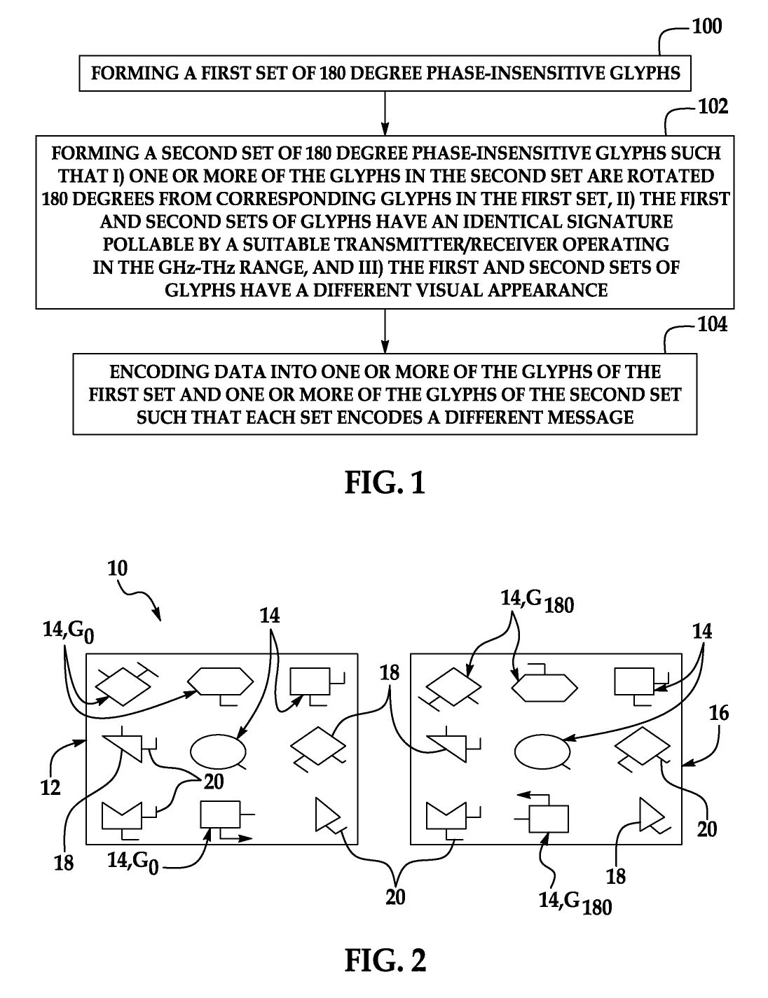

Referring now to FIG. 1, an embodiment of the method for generating a multi-modal deterrent is shown. The method generally includes forming a first set of 180° phase-insensitive glyphs, as shown at reference numeral 100; forming a second set of 180° phase-insensitive glyphs such that i) one or more of the glyphs in the second set are rotated 180° from corresponding glyphs in the first set, ii) the first and second sets of glyphs have an identical signature pollable by a suitable transmitter/receiver operating in the GHz-THz range, and iii) the first and second sets of glyphs have a different visual appearance, as shown at reference numeral 102; and encoding data into one or more of the glyphs of the first set and one or more of the glyphs of the second set such that each set encodes a different message, as shown at reference numeral 104.

FIG. 2 depicts an embodiment of the multi-modal security deterrent 10 formed via the method of FIG. 1. The deterrent 10 includes the first set 12 of 180° phase-insensitive glyphs 14 and the second set 16 of 180° phase-insensitive glyphs 14. The glyphs 14 may be printed on an object (not shown) using any suitable printing technique, including inkjet printing, dry electrophotography, liquid electrophotography, or other variable data printing techniques.

It is to be understood that the term “object” as used herein is to be interpreted broadly and may include, but is not limited to any type of object, product, document or package. Likewise, the term “package” is to be interpreted broadly herein to include any unit for containing a product, displaying a product, or otherwise identifying a branded good. Non-limitative examples of such packages include labels, anti-tamper strips (which tear when removal is attempted, thereby damaging both visual and electrical aspects (e.g., part of an antenna element 18 is torn such that it no longer reflects the correct spectral signal) of the deterrent 10, 10′ (see FIG. 4A), 10″ (see FIG. 5A)), boxes, bags, containers, clamshells, bands, tape, wraps, ties, bottles, vials, dispensers, inserts, other documents, or the like, or combinations thereof.

The glyphs 14 include at least one shape 18, at least one antenna element 20, or combinations thereof. Any shape 18 may be used, including regular geometric shapes (e.g., squares, rectangles, circles, triangles, etc.), irregular geometric shapes (e.g., stars, curvy lines, etc.), or combinations thereof. As shown in FIG. 2, some of the shapes 18 are diamonds, rectangles, ovals, or triangles. Furthermore, the antenna element(s) 18 may be a single line, multiple lines (e.g., forming an “L” shape or a “T” shape), regular or irregular shapes (see, e.g., FIG. 5A), or combinations thereof.

It is to be understood that one or more of the glyphs 14, G₁₈₀ in the second set 16 are rotated 180° from corresponding glyphs 14, G₀ in the first set 12. In an embodiment, all of the glyphs 14, G₀, G₁₈₀ are 180° phase-insensitive, and thus any of the glyphs 14 may be rotated as is desired. By the phrase “180° phase-insensitive”, it is meant that the phase invariance of the transmitter/receiver operating in the GHz-THz range (e.g., radar transceivers, capacitive readers, magnetic readers, terahertz readers, or combinations thereof) cannot differentiate between the glyphs 14, G₀ at angle θ in the range 0°≦θ≦180° and the same glyphs 14, G₁₈₀ at angle θ+180°. As non-limiting examples, phase equivalent angles include 0° and 180°, 45° and 225°, 90° and 270°, and 135° and 315°. The original glyphs 14, G₀ and the corresponding rotated glyphs 14, G₁₈₀ have an identical signature that is pollable by a suitable transmitter/receiver operating in the GHz-THz range. As such, the sets 12, 16 also have an identical transmitter/receiver readable signature.

The original glyphs 14, G₀ and the corresponding rotated glyphs 14, G₁₈₀ also provide the deterrent 10 with first and second sets 12, 16 that have a different visual appearance. As such, a visual based reading system/technology returns a different image for each set 12, 16.

Data may be encoded into one or more of the glyphs 14 in the first and second sets 12, 16. It is to be understood that the data that is encoded depends, at least in part, on whether the phase-insensitive glyphs 14 have been rotated/phase shifted. It is to be understood that the encoded message for the first set 12 will be equivalent to the encoded message for the second set 16. This is due to the phase invariant characteristics of the reading system/technology.

A signature which includes all non-rotated glyphs 14, G₀ has a predetermined number of bits that may be encoded, and the rotated glyphs 14, G₁₈₀ enable additional bits to be encoded. As such, a glyph-derived encoded sequence incorporates the original non-rotated glyphs 14, G₀ and the rotated glyphs 14, G₁₈₀. For example, G₀ versus G₁₈₀ is one bit of data per phase-insensitive glyph 14, G₀, G₁₈₀, so that N (number of glyphs) additional bits are added to the deterrent 10.

It is to be understood that a different encoding scheme may be used for each reading system/technique used. Furthermore, a different encoding scheme may be used for each reader system/technique based on the different combinations of angles used. As a non-limiting example, if 50 different types of antenna elements 20 and 4 phase angles are used to form the deterrent 10, the transmitter/receiver based system will have 50×4=200 possible combinations per antenna element 20. Due to the fact that the deterrent 10 includes two sets 12, 16 of glyphs 14, the vision based system in this non-limiting example will have 8×50=400 combinations. This translates into 7.64 bits of data per antenna element 20 for the transmitter/receiver approach and 8.64 bits of data for the visual approach. Each combination of {angle, antenna element type} may then represent an alphanumeric value as defined by the encoding scheme of the specific reading system/technology. It is to be understood that an individual deterrent 10 may be defined as a group of “N” antennae elements 20. A deterrent 10 with N elements 18 will then have a total of 200N combinations for the transmitter/receiver based system and 400N combinations for the vision based system.

The ability to encode with different schemes is possible, at least in part, because each reading system/technology has a different symbol look up table (mapping symbol to the specific information, e.g., character, encoded).

The encoding may be decided at the design phase of the campaign. It is to be understood that encryption of the original signal, mass serialization (which may include adding entropy to the string of characters), or any other method of rendering the information encoded in the deterrent 10 less predictable, more useful, or more difficult to reverse engineer may be employed.

In some instances, in addition to phase rotations, minute rotational adjustments may be made to the glyphs 14. Some software is able to reliably detect rotational skew adjustments as small as one tenth of one degree. This rotational artifact is transparent to certain spectral reading methods, so additional information may be encoded based on the number of available adjustments. For example, if the range of adjustments is from −2.5° to +2.5° with a step size of 0.1°, then 51 additional possibilities per glyph 14 are available for storing information. The 51 possibilities discussed here equates to more than 5.5 bits per glyph 14.

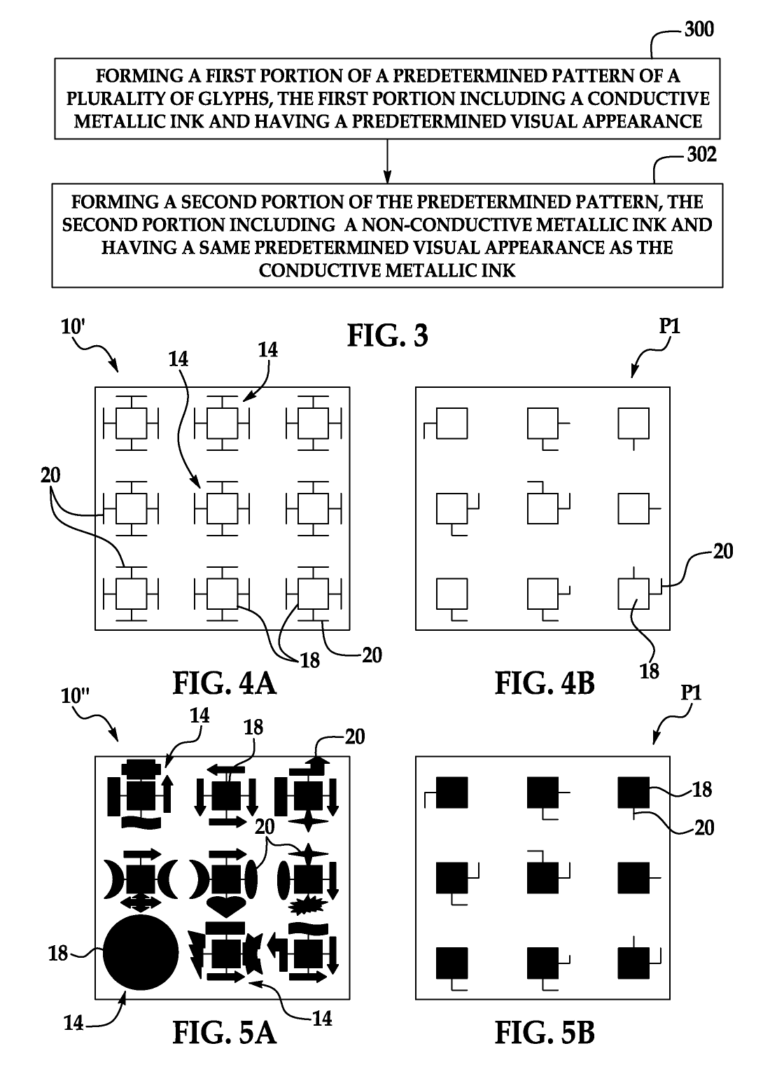

Referring now to FIG. 3, another embodiment of the method for generating another embodiment of the multi-modal deterrent 10′ is shown. The method generally includes forming a first portion of a predetermined pattern of a plurality of glyphs 14, the first portion including a conductive metallic ink and having a predetermined visual appearance, as shown at reference numeral 300; and forming a second portion of the predetermined pattern, the second portion including a non-conductive metallic ink and having a same predetermined visual appearance as the conductive metallic ink, as shown at reference numeral 302.

Referring now to FIGS. 4A and 5A, embodiments of the multi-model security deterrents 10′, 10″ formed via the method of FIG. 3 are depicted. It is to be understood that the deterrents 10′, 10″ shown in these figures represent the deterrents 10′, 10″ as they are visible to the human eye. FIGS. 4B and 5B respectively illustrate the portion P1 of the respective deterrents 10′, 10″ of FIGS. 4A and 5A that is visible when using a suitable reading technology. It is to be understood that the other human-eye visible portion of the deterrents 10′, 10″ (i.e., the portion shown in FIGS. 4A and 5A, but not shown in FIGS. 4B and 5B) is not visible when using the reading technology.

The multi-modal security deterrent 10′ (shown in FIG. 4A) includes a plurality of glyphs 14 which together form a predetermined visual pattern. While the glyphs 14 shown in FIG. 4A are all identical, it is to be understood that one or more of the glyphs 14 that make up the visual pattern may be different. A non-limiting example of a deterrent 10″ with different glyphs 14 is shown in FIG. 5A. As depicted in FIG. 5A, the glyphs 14 may include any desirable shape 18 and/or antenna element 20.

In these embodiments, a first portion P1 (shown in FIGS. 4B and 5B) of the predetermined visual patterns is formed of a conductive metallic ink and a second portion (shown, but not labeled, in FIGS. 4A and 5A in combination with the first portion P1) of the predetermined visual patterns is formed of a non-conductive ink. Together, these portions form the glyphs 14 of the deterrent 10′, 10″. It is to be understood that in the embodiments of the deterrent 10′, 10″, the second portion is either contiguous with or overlies the first portion to form a pattern whose portions are visually indistinguishable (i.e., the conductive and non-conductive inks together appear to be a single ink). As such, the naked eye generally cannot distinguish the first portion P1 from the second portion. Together, the first and second portions form a visually uniform pattern of glyphs 14.

The first portions P1 of the respective predetermined visual patterns of FIGS. 4A and 5A are formed of conductive ink, as such, these portions P1 are machine readable (i.e., readable via a radar transceiver, a capacitive reader, a magnetic reader, etc.). Whether the second portion is contiguous with or overlies the first portion P1, it is to be understood that the second portion, which is formed of non-conductive ink, is generally not readable via the transmitted/reflected (GHz/THz) signal, but is still readable via machine vision (e.g., visible light scanning). As such, the machine readable pattern (shown in FIGS. 4B and 5B) corresponds with the first portion P1, and thus is different from the visual pattern (which includes both the first and second portions). The authenticating pattern (i.e., first portion P1) is hidden in plain sight in these embodiments of the deterrent 10′, 10″, in part because the portions are visually indistinguishable.

It is to be understood that the portion P1 formed of conductive ink may also be encoded with data. Any desirable encoding scheme may be used in these embodiments. As a non-limiting example, one of four lengths may be used for each antenna, this equals 2 bits/antenna, thereby providing 4 bits of data.

The deterrents 10′, 10″ shown in FIGS. 4A and 5A may be formed via numerous techniques. In one embodiment, the first portion P1 is printed (e.g., via inkjet printing, dry or liquid electrophotography, or other suitable variable data printing techniques) on an object using a conductive metallic ink. As shown in FIGS. 4B and 5B, this portion P1 includes shapes 18 and/or antenna elements 20 that are desirable for the machine readable pattern. A second printing pass is then performed in which the non-conductive metallic ink is printed adjacent or over the first portion P1 to form the predetermined visual pattern (examples of which are shown in FIGS. 4A and 5A).

In another embodiment of generating the deterrent 10′, 10″, the first and second portions are printed using non-conductive ink. Such portions may be printed substantially simultaneously. The first portion P1 is then selectively exposed to a treatment which activates the non-conductive ink, thereby forming the conductive metallic ink. Non-limiting examples of such treatments include localized heating, localized ultraviolet curing, localized annealing, localized aligning, or any other technique that is suitable for transforming the desirable areas of the non-conductive ink to the conductive ink.

In still another embodiment, a sandwich approach is used to form the deterrent 10′, 10″. The first portion P1 is printed with conductive ink on a base layer substrate. This is followed by overlaying another substrate layer (e.g., a layer of foil, a plastic pull off sheet, a coating, or the like) on top of the printed conductive ink, thereby effectively concealing the printed symbology of the conductive ink. Still another printing pass is performed in which the machine vision-based encoding symbology (i.e., the visible printing pattern) is printed on the additional substrate layer.

In the embodiments shown in FIGS. 4A and 5A, the second portion generally includes additional antenna elements 20 that, together with the first portion P1, form glyphs 14 and complete the visual pattern. In some instances, the second portion includes the non-conductive ink established to form a desirable shape 18, rather than an antenna element 20 (see, e.g., the circle in FIG. 5A). It is to be understood that, as previously described, the various embodiments of the first and second portions may be established via multiple printing passes, conductive ink activation, and/or sandwiching.

Regardless of the method used to form the deterrent 10′, 10″, it is to be understood that additional antenna elements 20 may be faux/decoy visual antennas that contain no information. The patterns used may be entirely variable to further enhance ambiguity, thereby increasing the difficulty in ascertaining what aspect of the printed deterrent 10′, 10″ contains real information.

In any of the embodiments disclosed herein, copy detection patterns may also be incorporated into the deterrent 10, 10′, 10″ as a faux deterrent to confuse would be counterfeiters about which aspects are the actual deterrent 10, 10′, 10″, or to prevent unauthorized reproduction of visually authenticated data.

Furthermore, any of the deterrents 10, 10′, 10″ may be printed with inks having a pre-defined chemical makeup. This allows for additional validation that the deterrent 10, 10′, 10″ is authentic. Forensic ink analysis can be performed to validate that one or more glyphs 14 was/were printed using the prescribed ink for a print campaign. Some technology, such as terahertz imaging, has the ability to examine chemical composition when scanning. This allows for simultaneous spectral authentication via the terahertz reader and forensic authentication of the ink used in printing.

The system disclosed herein includes the multi-modal security deterrents 10, 10′, 10″, the deterrent readers, and a backend database at a secure registry. Generally, a security campaign involving the embodiments disclosed herein includes deterrent 10, 10′, 10″ design(s), the type of reading technologies to be used, encoding schemes which correspond to the reading technologies, and ink(s) and substrate(s)/object(s) used in printing the deterrent(s) 10, 10′, 10″. It is to be understood that the information for the security campaign is stored in the backend database for later use in product identification and authentication.

The secure registry also includes software which can generate the symbology and the encoded information for a deterrent 10, 10′, 10″. It is to be understood that such software may be operatively connected to the database (which stores security campaigns) to verify that duplicate deterrents 10, 10′, 10″ are not generated. Prior to creation of the deterrent 10, 10′, 10″, the software queries the database to check against pre-existing strings of encoded information. If the input string is not found in the database, then the corresponding symbology is created and the database is updated to reflect the creation of the deterrent 10, 10′, 10″. If the input string already exists in the database, then the software system can return an error message and deny the request to generate the symbology, and thus the deterrent 10, 10′, 10″.

The system may also remove defective deterrents during the printing/manufacturing process. As a non-limiting example, the multi-modal deterrent 10, 10′, 10″ contains a visually authenticable pattern on the surface and a covert terahertz readable pattern. During the process of printing the visually authenticable pattern, any deterrents 10, 10′, 10″ which fail visual inspection due to print or process defects are removed from the manufacturing line and placed in a bin. This bin, which now contains a number of deterrent 10, 10′, 10″ which failed Quality Assurance (QA), may then be scanned via a terahertz reader to poll all of the deterrents 10, 10′, 10″ in the bin. Each deterrent 10, 10′, 10″ in the bin is identified and the corresponding entry in the database is updated to indicate that the deterrent 10, 10′, 10″ will not be issued for deployment due to failing QA. It is to be understood that the combination of glyphs 14 and reading technologies is not limited to terahertz readers or sandwich deterrents 10, 10′, 10″, rather this approach may be extended to any combination of reading technologies where at least one technology is spectral (e.g., GHz or THz band) based and has the ability to poll the deterrents 10, 10′, 10″ via a spectral frequency band.

This approach provides many benefits. First, all of the deterrents 10, 10′, 10″ in the bin can be simultaneously polled and identified. This advantageously reduces manufacturing time by providing a relatively simple and efficient method for handling deterrents 10, 10′, 10″ which fail QA. Second, if a deterrent 10, 10′, 10″ marked as a QA failure appears in the field, one can immediately recognize that the deterrent 10, 10′, 10″ is either a forgery or the original deterrent 10, 10′, 10″ was obtained through illicit means. Third, since the covert terahertz readable pattern is unique for the given print run, it can encode substantially less information than the associated visually authenticable pattern. Finally, one of the modalities may be held in reserve and never employed until desirable for recall, auditing, etc.

While several embodiments have been described in detail, it will be apparent to those skilled in the art that the disclosed embodiments may be modified. Therefore, the foregoing description is to be considered exemplary rather than limiting.

What is claimed is:

1. A multi-modal security deterrent (10), comprising:
a first set (12) of 180° phase-insensitive glyphs (14);
a second set (16) of 180° phase-insensitive glyphs (14), one or more (14, G₁₈₀) of which are rotated 180° from corresponding glyphs (14, G₀) in the first set (12) such that the first and second sets (12, 16) of glyphs (14) have an identical signature pollable by a transmitter/receiver operating in the GHz-THz range and such that the first and second sets (12, 16) of glyphs (14) have a different visual appearance; and
data encoded in one or more of the glyphs (14) of the first set (12) and one or more of the glyphs (14) of the second set (16) such that each set (12, 16) encodes a different message.

2. The multi-modal security deterrent (10) as defined in claim 1 wherein the data encoded is based on whether the phase-insensitive glyphs (14) have been at least one of individually or collectively phase shifted between the sets (12, 16).

3. The multi-modal security deterrent (10) as defined in any of claim 1 or 2 wherein the signature is readable via a radar transceiver, a capacitive reader, a magnetic reader, a terahertz reader, or combinations thereof.

4. The multi-modal security deterrent (10) as defined in any of claims 1 through 3 wherein the glyphs (14) include at least one shape (18), at least one antenna element (20), or combinations thereof.

5. The multi-modal security deterrent (10) as defined in any of claims 1 through 4 wherein the signature of non-rotated glyphs (14, G₀) has a predetermined number of bits and wherein rotated glyphs (14, G₁₈₀) enable additional bits to be added to the security deterrent (10).

6. The multi-modal security deterrent (10) as defined in any of claims 1 through 5 wherein the first and second sets (12, 16) are printed on an anti-tamper strip.

7. A method for generating a multi-modal security deterrent (10), comprising:
forming a first set (12) of 180° phase-insensitive glyphs (14);
forming a second set (16) of 180° phase-insensitive glyphs (14) such that i) one or more of the glyphs (14, G₁₈₀) in the second set (16) are rotated 180° from corresponding glyphs (14, G₀) in the first set (12), ii) the first and second sets (12, 16) of glyphs (14) have an identical signature pollable by a suitable transmitter/receiver operating in the GHz-THz range, and iii) the first and second sets (12, 16) of glyphs (14) have a different visual appearance; and
encoding data into one or more of the glyphs (14) of the first set (12) and one or more of the glyphs (14) of the second set (16) such that each set (12, 16) encodes a different message.

8. A multi-modal security deterrent (10), comprising:
a plurality of glyphs (14) having a predetermined visual pattern, including:
a first portion (P1) of the predetermined visual pattern formed of a conductive metallic ink; and
a second portion of the predetermined visual pattern formed of a non-conductive metallic ink, wherein the conductive metallic ink and the non-conductive metallic ink are visually indistinguishable.

9. The multi-modal security deterrent (10) as defined in claim 8 wherein the predetermined visual pattern is different from a machine readable pattern of the plurality of glyphs (14).

10. The multi-modal security deterrent (10) as defined in any of claim 8 or 9 wherein the first portion (P1) is encoded with data.

11. The multi-modal security deterrent (10) as defined in any of claims 8 through 10 wherein the plurality of glyphs (14) is printed on an anti-tamper strip.

12. A method for generating a multi-modal security deterrent (10), comprising:
forming a first portion (P1) of a predetermined pattern of a plurality of glyphs (14), the first portion (P1) including a conductive metallic ink and having a predetermined visual appearance; and
forming a second portion of the predetermined pattern, the second portion including a non-conductive metallic ink and having a same predetermined visual appearance as the conductive metallic ink.

13. The method as defined in claim 12 wherein forming the first portion (P1) is accomplished by:
printing the first portion (P1) with the non-conductive metallic ink; and
selectively exposing the first portion (P1) to a treatment which activates the non-conductive metallic ink and forms the conductive metallic ink.

14. The method as defined in claim 13 wherein the treatment is heating, ultraviolet curing, annealing, aligning, or combinations thereof.

15. The method as defined in any of claims 12 through 14, further comprising encoding data in the first portion (P1).
